(19) United States
(12) Patent Application Publication
(10) Pub. No.: US 2018/0232074 A1
(43) Pub. Date: Aug. 16, 2018

(54) BEZEL FRAME FOR TOUCH SCREEN AND TOUCH SCREEN HAVING THE SAME

(71) Applicants: Boe Technology Group Co., Ltd., Beijing (CN); Hefei Xinsheng Optoelectronics Technology Co., Ltd., Anhui (CN)

(72) Inventors: Yifei Zhan, Beijing (CN); Dayu Zhang, Beijing (CN); Kun Li, Beijing (CN); Yueyuan Zhang, Beijing (CN)

(21) Appl. No.: 15/513,616

(22) PCT Filed: May 13, 2016
(86) PCT No.: PCT/CN2016/081971

§ 371 Date: Mar. 23, 2017

(30) Foreign Application Priority Data
Feb. 25, 2016 (CN) 201620143557.5

(51) Int. Cl. G06F 3/044; H05K 1/14; H05K 5/00

(52) U.S. Cl. CPC G06F 3/044; H05K 1/147; H05K 5/0017; H05K 2201/10128; H05K 2201/2018; H05K 2201/10151; G06F 2203/04102

(57) ABSTRACT

A bezel frame for a touch screen is disclosed. The touch screen includes a touch panel component, a plurality of flexible printed circuit boards, a plurality of signal processing printed circuit boards, and peripheral wirings. The bezel frame includes an inner surface defining a groove for accommodating an edge portion of the touch panel component, the plurality of flexible printed circuit boards, the plurality of signal processing printed circuit boards, and the peripheral wirings.

### TECHNICAL FIELD

The present disclosure relates to the field of display technologies, and particularly to a bezel frame for a touch screen, as well as a touch screen having the bezel frame.

### BACKGROUND

As a novel human-machine interaction device, the touch screen has found wide applications. Due to their high sensitivity and being supportive of multi-touch, capacitive touch screens have become more and more popular in consumer electronic products. However, in the applications of super-sized touch screens, infra-red touch screens still dominate.

This is because in the case of a super-sized screen, the capacitive touch screen is difficult to assemble. Specifically, there are a large number of touch driving electrodes and touch sensing electrodes in the capacitive touch screen, each of which requires a respective lead wire to receive/transmit signals from/to a signal processing circuit. The respective lead wires and the signal processing circuit may occupy a large space, which poses a challenge to the assembling of the screen and the bezel.

### SUMMARY

In view of this, it would be advantageous to provide a bezel frame for a touch screen, which is provided with a groove for accommodation of peripheral electronic devices of the touch screen. It would also be desirable to provide a touch screen that employs such a bezel frame.

According to an aspect of the present disclosure, a bezel frame for a touch screen is provided. The touch screen comprises a touch panel component, a plurality of flexible printed circuit boards electrically connected to the touch panel component, a plurality of signal processing printed circuit boards each operable to interact with the touch panel component via a respective one of the plurality of flexible printed circuit boards, and peripheral wirings for providing electrical connections between the plurality of signal processing printed circuit boards. The bezel frame comprises an inner surface defining a groove for accommodating an edge portion of the touch panel component, the plurality of flexible printed circuit boards, the plurality of signal processing printed circuit boards, and the peripheral wirings.

In some embodiments, the groove extends along an outline of the bezel frame to form a ring-shaped groove.

In some embodiments, the groove extends along only a section of an outline of the bezel frame.

In some embodiments, the touch screen further comprises a display panel component and a display peripheral circuit, wherein the display panel component and the touch panel component are stacked on top of each other to form a touch display panel, and the groove is further adapted to accommodation of the display peripheral circuit and an edge portion of the touch display panel.

In some embodiments, the touch screen further comprises a display panel component and a display peripheral circuit. The touch panel component is embedded into the display panel component to form a touch display panel. The groove is further adapted to accommodation of the display peripheral circuit and an edge portion of the touch display panel.

According to another aspect of the present disclosure, a touch screen is provided which comprises the bezel frame as described above.

In some embodiments, the touch screen is a capacitive touch screen.

In some embodiments, the touch screen has a type selected from the group consisting of OGS, GFF, GF and GG.

These and other aspects of the present disclosure will be apparent from and elucidated with reference to the embodiment(s) described hereinafter.

### BRIEF DESCRIPTION OF THE DRAWINGS

FIG. 1 is a schematic diagram of a bezel frame according to an embodiment of the present disclosure;

FIG. 2 is a cross-sectional view of the bezel frame according to the embodiment of FIG. 1 taken along line A-A; and

FIG. 3 is schematic diagram of internal parts of a touch screen according to an embodiment of the present disclosure.

### DETAILED DESCRIPTION

The present disclosure will now be described more fully with reference to the accompanying drawings in which exemplary embodiments of the present disclosure are shown. However, the present disclosure may be embodied in various manners, and is not to be interpreted as limited to the embodiments described herein. Rather, these embodiments are provided to render the present disclosure thorough and complete, and to fully convey the scope of the present disclosure to those skilled in the art. Like reference numerals refer to like elements throughout. The drawings are not necessarily drawn to scale.

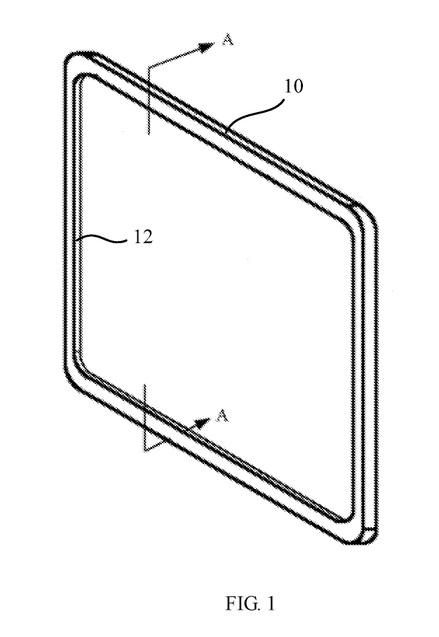

FIG. 1 is a schematic diagram of a bezel frame 10 according to an embodiment of the present disclosure.

Referring to FIG. 1, the bezel frame 10 has a substantially rectangular outline. Specifically, the bezel frame 10 is illustrated as having a rounded rectangular shape, although other embodiments are possible.

The bezel frame 10 has an inner surface 12 which defines a groove (not shown in this figure). The groove provides an assembly space. When the bezel frame 10 is assembled with a touch screen, the groove can accommodate an edge portion of the touch screen and peripheral electronic devices, as will be discussed later.

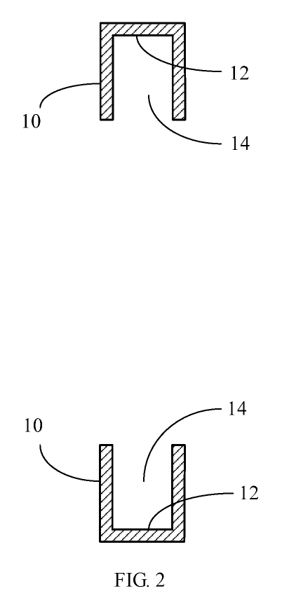

FIG. 2 is a cross-sectional view of the bezel frame 10 according to the embodiment of FIG. 1 taken along line A-A.

As is shown, the inner surface 12 of the bezel frame 10 defines a groove 14. In this example, both the upper inner surface 12 and the lower inner surface 12 of the bezel frame 10 define the groove 14.

In some embodiments, the groove 14 extends along the outline of the bezel frame 10 to form a ring-shaped groove. This may provide sufficient space for accommodation. Moreover, the four edges of the touch screen, in this case, may be accommodated in the groove, which improves the fastness of the assembling of the bezel frame 10 and the touch screen. Furthermore, the bezel frame 10 having the ring-shaped groove may function as a general frame since it is suitable for assembling with various touch screens having the same size.

In some embodiments, the groove 14 extends along only a section of the outline of the bezel frame 10. That is, the groove 14 is formed at only a predetermined position on the inner surface 12. For example, the groove 14 may be formed on only the upper inner surface 12 shown in FIG. 2. At the section of the inner surface 12 where no groove is formed, the bezel frame 10 has a larger thickness and thus may provide an enhanced mechanical strength.

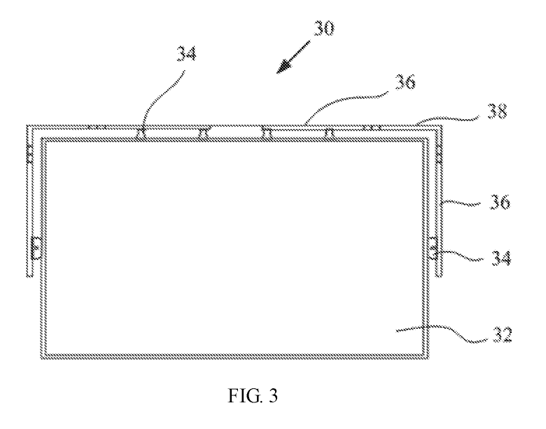

FIG. 3 is schematic diagram of internal parts of a touch screen 30 according to an embodiment of the present disclosure.

In this embodiment, the touch screen 30 is a capacitive touch screen. Specifically, the touch screen 30 includes a display panel component 32, a plurality of flexible printed circuit boards (FPC) 34, a plurality of signal processing printed circuit board (PCB) 36, and peripheral wirings 38.

The touch panel component 32 includes a plurality of rows of driving electrodes and a plurality of columns of sensing electrodes. In general, each of the rows of driving electrodes is connected to a driving signal line, and each of the columns of sensing electrodes is connected to a sensing signal line. These signal lines are used to transmit driving signals and sensing signals.

The plurality of flexible printed circuit boards 34 are electrically connected to the touch panel component 32. Specifically, each of the plurality of flexible printed circuit boards 34 may include a plurality of driving signal lines and/or a plurality of sensing signal lines that are connected to the touch panel component 32.

In an application of a super-sized touch screen, there are a great number of driving signal lines and sensing signal lines that are distributed in the length direction and the width direction of the touch screen. In this case, the existence of a plurality of flexible printed circuit boards 34 is advantageous because it is unnecessary to arrange all the signal lines to a single flexible printed circuit board using very long connection lines.

In the example shown in FIG. 3, the left side and right side of the touch panel component 32 are each provided with a respective flexible printed circuit board 34, and the upper side of the touch panel component 32 is provided with multiple flexible printed circuit boards 34. Each of the flexible printed circuit boards 34 may be connected to a respective driving signal line or sensing signal line without the use of long connection lines. This may reduce the latency of the signal, and thus improve the detection accuracy of the touch position.

The touch screen 30 further includes a plurality of signal processing printed circuit boards 36. Each of the signal processing printed circuit boards 36 is operable to interact with the touch panel component 32 via a respective one of the plurality of flexible printed circuit boards 34. Specifically, the signal processing printed circuit boards 36 provide driving signals to the touch panel component 32 via the driving signal lines and receive sensing signals from the touch panel component 32 via the sensing signal lines.

The touch screen 30 further includes peripheral wirings 38 that may provide electrical connections among the plurality of signal processing printed circuit boards 36. In some embodiments, one of the signal processing printed circuit boards 36 acts as a master controller. In some embodiments, the touch screen 30 may include a separate master controller (not shown). In either case, the sensing signals may be transmitted to the master controller for detection of the touch position.

Exemplary integral parts of the touch screen 30 have been described above.

Referring back to FIG. 2, the groove 14 may be used to accommodate an edge portion of the touch panel component 32, the plurality of flexible printed circuit boards 34, the plurality of signal processing printed circuit board 36, and the peripheral wirings 38. As such, it is unnecessary to dispose complicated wirings at other positions (e.g., a back plate) of the touch screen, enabling a compact structure of the touch screen. This is of particular advantage in the case of the super-sized touch screen.

As is known, the touch screen 30 further includes a display panel component and an associated display peripheral circuit, which are not shown for simplicity.

The display panel component may include gate lines, data lines and a pixel array. In an exemplary embodiment, the display peripheral circuit may include, among others, a gate driver circuit for providing gate driving signals for the gate lines, a source driver circuit for providing data signals for the data lines, and a timing controller. The display peripheral circuit may be formed on the signal processing printed circuit board 36, or it may be formed on a separate display signal processing PCB.

In some embodiments, the display panel component and the touch panel component are stacked on top of each other to form a touch display panel. For example, in an add-on touch screen, the touch panel component is overlaid on the display panel component.

In some embodiments, the touch panel component is embedded into the display panel component to form a touch display panel. Examples of such a touch screen include, but are not limited to, the in-cell type of touch screens.

In an example, the touch screen according to embodiments of the present disclosure may have a type of any one of OGS, GFF, GF and GG OGS refers to a touch screen where both the driving electrodes TX and the sensing electrodes RX are fabricated on a glass substrate. GFF refers to a touch screen where two films that are respectively fabricated with the driving electrodes TX and the sensing electrodes RX are fitted together with a glass substrate. GF refers to a touch screen where the two surfaces of a film are respectively fabricated with the driving electrodes TX and the sensing electrodes RX. GG refers to a touch screen where a glass substrate on which the touch electrodes TX are fabricated is fitted together with another glass substrate on which the sensing electrodes RX are fabricated.

Although embodiments of the present disclosure are described above in connection to capacitive touch screens, the present disclosure is not limited thereto. The bezel frame according to embodiments of the present disclosure may also be applied to other types of touch screens.

Variations to the disclosed embodiments can be understood and effected by the skilled person in practicing the claimed subject matter, from a study of the drawings, the disclosure, and the appended claims. In the claims, the word “comprises” or “comprising” does not exclude other elements or steps, “a plurality of” refers to “two or more”, and the indefinite article “a” or “an” does not exclude a plurality. The mere fact that certain measures are recited in mutually different dependent claims does not indicate that a combination of these measures cannot be used to advantage.

1. A bezel frame for a touch screen, the touch screen comprising a touch panel component, a plurality of flexible printed circuit boards electrically connected to the touch panel component, a plurality of signal processing printed circuit boards each operable to interact with the touch panel component via a respective one of the plurality of flexible printed circuit boards, and peripheral wirings for providing electrical connections between the plurality of signal processing printed circuit boards, the bezel frame comprising:
an inner surface defining a groove for accommodating an edge portion of the touch panel component, the plurality of flexible printed circuit boards, the plurality of signal processing printed circuit boards, and the peripheral wirings.

2. The bezel frame of claim 1, wherein the groove extends along an outline of the bezel frame to form a ring-shaped groove.

3. The bezel frame of claim 1, wherein the groove extends along only a section of an outline of the bezel frame.

4. The bezel frame of claim 1, wherein the touch screen further comprises a display panel component and a display peripheral circuit, wherein the display panel component and the touch panel component are stacked on top of each other to form a touch display panel, and wherein the groove is further adapted to accommodation of the display peripheral circuit and an edge portion of the touch display panel.

5. The bezel frame of claim 1, wherein the touch screen further comprises a display panel component and a display peripheral circuit, wherein the touch panel component is embedded into the display panel component to form a touch display panel, and wherein the groove is further adapted to accommodation of the display peripheral circuit and an edge portion of the touch display panel.

6. A touch screen comprising the bezel frame of claim 1.

7. The touch screen of claim 6, wherein the touch screen is a capacitive touch screen.

8. The touch screen of claim 7, wherein the touch screen has a type selected from the group consisting of OGS, GFF, GF and GG.

9. The bezel frame of claim 2, wherein the touch screen further comprises a display panel component and a display peripheral circuit, wherein the display panel component and the touch panel component are stacked on top of each other to form a touch display panel, and wherein the groove is further adapted to accommodation of the display peripheral circuit and an edge portion of the touch display panel.

10. The bezel frame of claim 3, wherein the touch screen further comprises a display panel component and a display peripheral circuit, wherein the display panel component and the touch panel component are stacked on top of each other to form a touch display panel, and wherein the groove is further adapted to accommodation of the display peripheral circuit and an edge portion of the touch display panel.

11. The bezel frame of claim 2, wherein the touch screen further comprises a display panel component and a display peripheral circuit, wherein the touch panel component is embedded into the display panel component to form a touch display panel, and wherein the groove is further adapted to accommodation of the display peripheral circuit and an edge portion of the touch display panel.

12. The bezel frame of claim 3, wherein the touch screen further comprises a display panel component and a display peripheral circuit, wherein the touch panel component is embedded into the display panel component to form a touch display panel, and wherein the groove is further adapted to accommodation of the display peripheral circuit and an edge portion of the touch display panel.

13. A touch screen comprising the bezel frame of claim 2.

14. A touch screen comprising the bezel frame of claim 3.

15. A touch screen comprising the bezel frame of claim 4.

16. A touch screen comprising the bezel frame of claim 5.

17. A touch screen comprising the bezel frame of claim 9.

18. A touch screen comprising the bezel frame of claim 10.

19. A touch screen comprising the bezel frame of claim 11.

20. A touch screen comprising the bezel frame of claim 12.
